(19) United States
(12) Patent Application Publication
(10) Pub. No.: US 2006/0257791 A1
(43) Pub. Date: Nov. 16, 2006

(54) Method for forming conductive line of semiconductor device

(75) Inventors: Seung Bum Kim, Seoul (KR); Ki Won Nam, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/169,943

(22) Filed: Jun. 30, 2005

(30) Foreign Application Priority Data
May 16, 2005 (KR) 10-2005-0040624

(51) Int. Cl. G03F 7/26

(52) U.S. Cl. 430/313; 430/311

(57) ABSTRACT

A method for forming a conductive line of a semiconductor device is disclosed. The method includes forming a photoresist film pattern defining a conductive line region on a stacked structure of a conductive layer and a hard mask layer disposed on a semiconductor substrate, etching the hard mask layer using the photoresist film pattern as an etching mask to form a hard mask layer pattern, removing the photoresist film pattern, and etching the conductive layer using the hard mask layer pattern as an etching mask to form a conductive layer pattern, wherein the etching process and the removal process are performed via an in-situ process.

### BACKGROUND OF THE INVENTION

1. Field of the Invention

The present invention generally relates to a method for forming a conductive line of a semiconductor device, and more specifically, to a method for forming a conductive line of a semiconductor device wherein processes are performed via an in-situ method in one chamber instead of three different chambers to secure mask and photo processes, thereby improving operation characteristics and reliability of the semiconductor device.

2. Description of the Related Art

In accordance with a conventional method for forming a conductive line of a semiconductor device, a stacked structure of a polysilicon layer, a metal layer and a hard mask layer (not shown) is formed on a semiconductor substrate. A photoresist film pattern (not shown) is then formed on the hard mask layer (not shown).

Next, the hard mask layer (not shown) is etched using the photoresist film pattern as an etching mask to form a hard mask layer pattern (not shown). The photoresist film pattern is then removed.

Thereafter, the metal layer and the polysilicon layer are etched using the hard mask layer pattern as an etching mask to form a conductive line.

Preferably, the etching process of the hard mask layer, the removal process of the photoresist film pattern, and the etching process of the metal layer and the polysilicon layer are performed in separated chambers.

An etch bias refers a width variation of a pattern. That is, the etch bias defines the difference between a develop inspection critical dimension (“DICD”) and a final inspection critical dimension (“FICD”). The etch bias in a peripheral circuit region where the mask patterns are sparse becomes in a range of 20 nm to 40 nm. An Optical Proximity Correction (“OPC”) method is used to adjust a width of the mask pattern in the peripheral circuit region. However, there is the limit to the method.

FIG. 1 is a photograph illustrating a conventional method for forming a conductive line of a semiconductor device.

Referring to FIG. 1, a pattern profile of the conductive line is not uniformed.

TABLE 1

| | Cell Region | Peripheral Circuit Region |
|---|---|---|
| DICD | 116 nm | 138 nm |
| FICD | 119 nm | 168 nm |
| Etch Bias | 3 nm | 30 nm |

Table 1 shows FICDs, DICDs, and etch biases in a cell region and a peripheral circuit region respectively.

Referring to Table 1, there is substantial difference between the etch biases in the cell region and the peripheral circuit region.

In accordance with the above-described conventional method for forming a conductive line of a semiconductor device, a top profile of the conductive line is irregularly formed to have unstable monitoring CD and damage of a hard mask nitride film. As a result, the SAC (Self Align Contact) etch barrier layer is lowered during the subsequent process.

### SUMMARY OF THE INVENTION

Accordingly, it is an object of the present invention to provide a method for forming a conductive line of a semiconductor device wherein processes are performed via an in-situ method in one chamber instead of three different chambers to secure mask and photo processes, thereby improving operation characteristics and reliability of the semiconductor device.

In order to achieve the above object of the present invention, there is provided a method for forming a conductive line of a semiconductor device, comprising the steps of: (a) forming a photoresist film pattern defining a conductive line region on a stacked structure of a conductive layer and a hard mask layer disposed on a semiconductor substrate, (b) etching the hard mask layer using the photoresist film pattern as an etching mask to form a hard mask layer pattern, (c) removing the photoresist film pattern, and (d) etching the conductive layer using the hard mask layer pattern as an etching mask to form a conductive layer pattern, wherein the steps (b) through (d) are performed via an in-situ process.

### BRIEF DESCRIPTION OF THE DRAWINGS

FIG. 1 is a photograph illustrating a conventional method for forming a conductive line of a semiconductor device.

FIG. 2 is a cross-sectional view illustrating a plasma chamber used in formation of a conductive line of a semiconductor device according to the present invention.

FIGS. 3a through 3f are cross-sectional views illustrating a method for forming a conductive line of a semiconductor device according to a preferred embodiment of the present invention.

FIGS. 4a and 4b are photographs illustrating a method for forming a conductive line of a semiconductor device according to a preferred embodiment of the present invention.

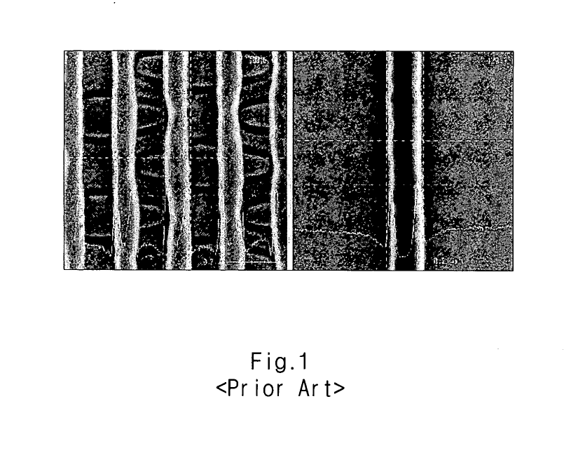

### DETAILED DESCRIPTION OF THE PREFERRED EMBODIMENTS

Reference will now be made in detail to exemplary embodiments of the present invention. Wherever possible, the same reference numbers will be used throughout the drawings to refer to the same or like parts.

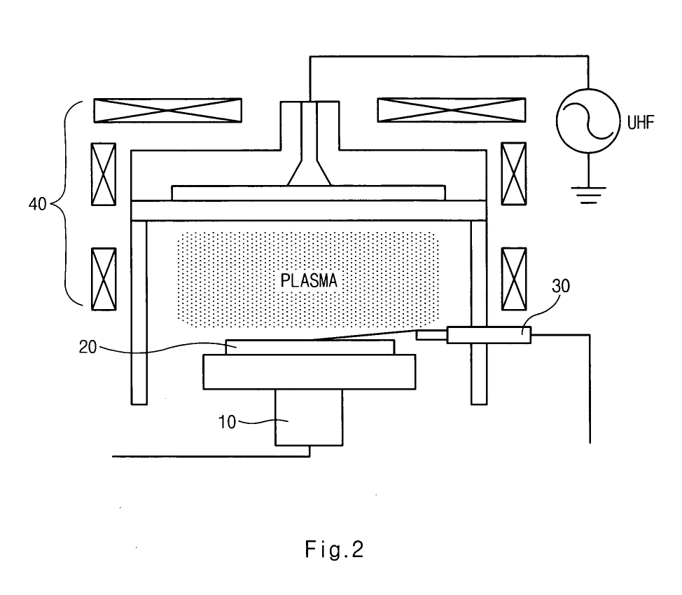

FIG. 2 is a cross-sectional view illustrating a plasma chamber used in formation of a conductive line of a semiconductor device according to the present invention.

Referring to FIG. 2, a microwave ECR source plasma chamber has a wafer chuck 10 disposed thereunder in order to hold a wafer. The chamber has at least one coil 40 on inner sidewalls of a top portion, a middle portion and a bottom portion thereof respectively.

Here, uniformity of plasma and an etch bias may be controlled by adjusting a gap between plasma and a wafer 30 via the coil 40.

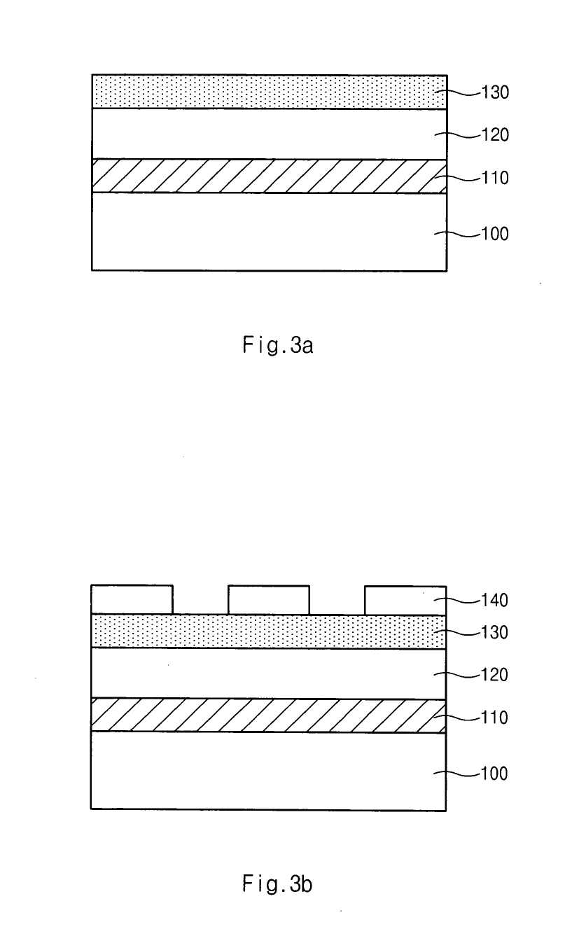

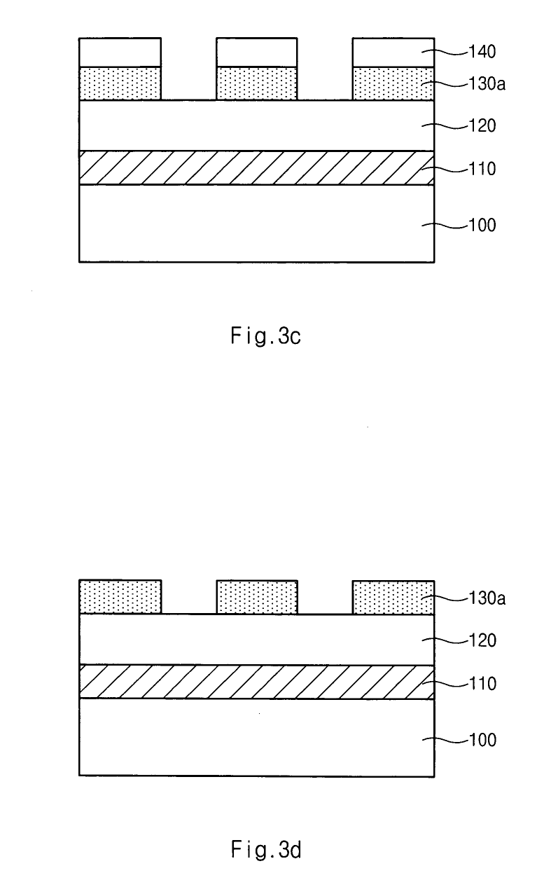

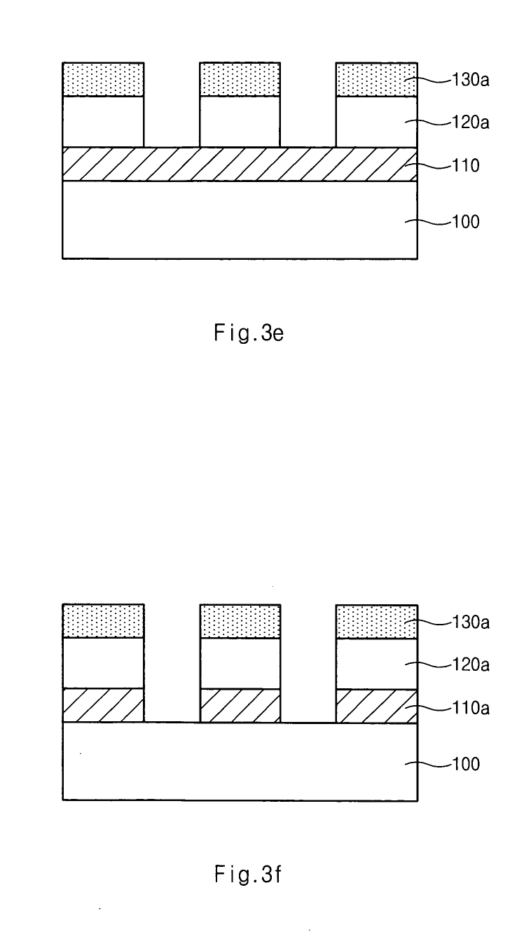

FIGS. 3a through 3f are cross-sectional views illustrating a method for forming a conductive line of a semiconductor device according to a preferred embodiment of the present invention.

Referring to FIG. 3a, a polysilicon layer 110, a metal layer 120 and a hard mask layer 130 are formed on a semiconductor substrate. Preferably, the metal layer 120 comprises a tungsten silicide, and the hard mask layer 130 comprises a stacked structure of an antireflective film and a nitride film.

Referring to FIG. 3b, a photoresist film pattern 140 defining a conductive line region is formed on the hard mask layer 130.

Referring to FIGS. 3c through 3f, the hard mask layer 130, the metal layer 120 and the polysilicon layer 110 are sequentially etched using the photoresist film pattern 140 as an etching mask. Preferably, each etching process further comprises an over-etching process.

In addition, the etching process is performed via an in-situ process in the microwave ECR source plasma chamber as shown in FIG. 2.

Referring to FIG. 3c, the hard mask layer 130 is etched using the photoresist film pattern 140 to form a hard mask layer pattern 130a. Preferably, the etching process is performed using a mixed plasma source containing SF₆, CHF₃ and O₂ at a pressure ranging from 5 mT to 10 mT and having a flow rate ranging from 100 sccm to 150 sccm, an ECR source power ranging from 800 W to 1500 W, and a RF bias power ranging from 30 W to 50 W.

Preferably, a ratio of a flow rate of SF₆ to that of CHF₃ ranges from 1:10 to 2:10, and a flow rate of O₂ ranges from 2 sccm to 5 sccm. Preferably, electric current flowing in the coils at the top portion, the middle portion, and the bottom portion of the chamber in the etching process preferably ranges from 25 A to 30 A, from 25 A to 30 A, and from 10 A to 15 A, respectively.

Next, the over-etching process is performed using an NF₃ plasma source having a flow rate ranging from 80 sccm to 120 sccm at an RF bias power ranging 80 W to 100 W. Preferably, electric current flowing in the coils at the top portion and the middle portion of the chamber in the over-etching process respectively ranges from 25 A to 30 A, and that at the bottom portion of the chamber is 0 A.

Referring to FIG. 3d, the photoresist film pattern 140 is removed. Preferably, the removal process for the photoresist film pattern 140 is performed at a pressure ranging from 7 mT to 10 mT, a source power ranging from 600 W to 1000 W, and an RF bias power ranging from 20 W to 40 W. Preferably, electric current flowing in the coils at the top portion and the middle portion of the chamber in the removal process respectively ranges from 25 A to 30 A, and that at the bottom portion of the chamber is 0 A.

Referring to FIG. 3e, the metal layer 120 is etched using the hard mask layer pattern 130a as an etching mask to form a metal layer pattern 120a. Preferably, the etching process is performed using a mixed plasma source containing Cl₂, O₂, N₂ and NF₃ at a pressure ranging from 2 mT to 4 mT, a source power ranging from 800 W to 1000 W, and an RF bias power ranging from 40 W to 70 W. Preferably, electric current flowing in the coils at the top portion and the middle portion of the chamber in the etching process respectively range from 25 A to 30 A, and that at the bottom portion of the chamber is 0 A.

Preferably, flow rates of Cl₂, NF₃, N₂, and O₂ in the mixed plasma source range from 50 sccm to 70 sccm, from 50 sccm to 70 sccm, from 40 sccm to 60 sccm, and 2 sccm to 10 sccm respectively.

On the other hand, the over-etching process for the metal layer 120 is preferably performed using a plasma source containing Cl₂ having a flow rate ranging from 10 sccm to 30 sccm and CF₄ having a flow rate ranging from 50 sccm to 70 sccm.

Referring to FIG. 3f, the polysilicon layer 110 is etched using the hard mask layer pattern 130a and the metal layer pattern 10a as an etching mask. Preferably, the etching process is performed using a mixed plasma source containing HBr and O₂ at a pressure ranging from 30 mT to 60 mT, a source power ranging from 600 W to 900 W. Preferably, electric current flowing in the coils at the top portion and the middle portion of the chamber in the etching process respectively ranges from 25 A to 30 A, and that at the bottom portion of the chamber is 0 A.

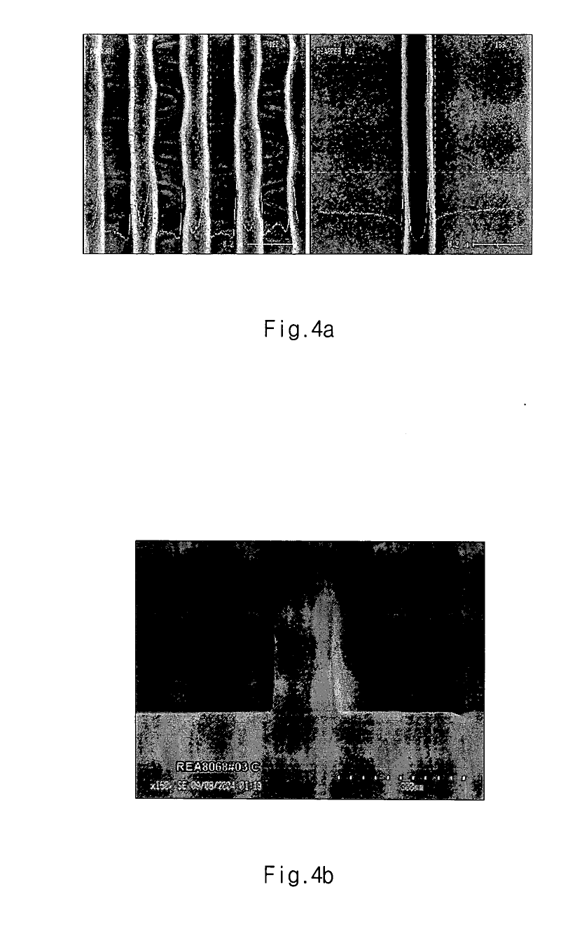

FIGS. 4a and 4b are cross-sectional photographs illustrating a method for forming a conductive line of a semiconductor device according to a preferred embodiment of the present invention.

Referring to FIGS. 4a and 4b, there are respectively a top view and a cross-sectional view illustrating the improved top profile of the conductive line after the formation of the conductive line.

TABLE 2

| | Cell Region | Peripheral Circuit Region |
|---|---|---|
| DICD | 116 nm | 138 nm |
| FICD | 119 nm | 138 nm |
| Etch Bias | 3 nm | 0 nm |

Table 2 shows FICDs, DICDs, and etch biases in a cell region and a peripheral circuit region respectively.

Referring to Table 2, the difference between the etch biases in the cell region and the peripheral circuit region becomes equal to or smaller than 3 nm so as to have the improved etch biases in the cell region and the peripheral circuit region.

As described above, the method for forming a conductive line of a semiconductor device in accordance with the present invention provides improved process time and margin by performing processes via an in-situ process in one chamber instead of three different chambers to prevent damage of the hard mask nitride layer.

In addition, the difference between the etch biases in the cell region and the peripheral circuit region is substantially decreased to secure the mask and photolithography process, thereby improving the operation characteristics and reliability of the semiconductor device.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

What is claimed is:

1. A method for forming a conductive line of a semiconductor device, comprising the steps of:
(a) forming a photoresist film pattern defining a conductive line region on a stacked structure of a conductive layer and a hard mask layer disposed on a semiconductor substrate;
(b) etching the hard mask layer using the photoresist film pattern as an etching mask to form a hard mask layer pattern;
(c) removing the photoresist film pattern; and
(d) etching the conductive layer using the hard mask layer pattern as an etching mask to form a conductive layer pattern,
wherein the steps (b) through (d) are performed via an in-situ process.

2. The method according to claim 1, wherein the conductive line is one of a word line, a bit line or a metal line.

3. The method according to claim 1, wherein the in-situ process is performed in a microwave ECR (Electron Cyclotron Resonance) source plasma chamber.

4. The method according to claim 3, wherein a top portion, a middle portion and a bottom portion of the chamber have at least one coil respectively.

5. The method according to claim 3, wherein the step (b) is performed using a mixed plasma source containing SF₆, CHF₃ and O₂ at a pressure ranging from 5 mT to 10 mT and having a flow rate ranging from 100 sccm to 150 sccm, an ECR source power ranging from 800 W to 1500 W, and a RF bias power ranging from 30 W to 50 W.

6. The method according to claim 5, wherein a ratio of a flow rate of SF₆ to that of CHF₃ ranges from 1:10 to 2:10, and a flow rate of O₂ ranges from 2 sccm to 5 sccm.

7. The method according to claim 4, wherein electric current flowing in the coils at the top portion, the middle portion, and the bottom portion in the step (b) ranges from 25 A to 30 A, from 25 A to 30 A, and from 10 A to 15 A respectively.

8. The method according to claim 3, wherein the step (c) is performed at a pressure ranging from 7 mT to 10 mT, a source power ranging from 600 W to 1000 W, and an RF bias power ranging from 20 W to 40 W.

9. The method according to claim 4, wherein electric current flowing in the coils at the top portion and the middle portion in the step (c) respectively ranges from 25 A to 30 A, and that at the bottom portion is 0 A.

10. The method according to claim 3, wherein the step (d) is performed using a mixed plasma source containing Cl₂, O₂, N₂ and NF₃ at a pressure ranging from 2 mT and 4 mT, a source power ranging from 800 W to 1200 W, and an RF bias power ranging from 40 W to 70 W.

11. The method according to claim 10, wherein flow rates of Cl₂, NF₃, N₂, and O₂ range from 50 sccm to 70 sccm, from 50 sccm to 70 sccm, from 40 sccm to 60 sccm, and from 2 sccm to 10 sccm respectively.

12. The method according to claim 4, wherein electric current flowing in the coils at the top portion and the middle portion in the step (d) respectively ranges from 25 A to 30 A, and that at the bottom portion is 0 A.

13. The method according to claim 3, wherein the steps (b) and (d) further comprise performing an over-etching process respectively.

14. The method according to claim 13, wherein the step (b) is performed using an NF₃ plasma source having a flow rate ranging from 80 sccm to 120 sccm at an RF bias power ranging 80 W to 100 W.

15. The method according to claim 13, wherein electric current flowing in the coils at the top portion and the middle portion in the step (b) respectively ranges from 25 A to 30 A, and that at the bottom portion is 0 A.

16. The method according to claim 13, wherein the step (d) is performed using a plasma source containing HBr and O₂ at a pressure ranging from 30 mT to 60 mT, a source power ranging from 600 W to 900 W, and an RF bias power ranging from 10 W to 20 W.

17. The method according to claim 13, wherein the step (d) is performed using a plasma source containing Cl₂ having a flow rate ranging from 10 sccm to 30 sccm and CF₄ having a flow rate ranging from 50 sccm to 70 sccm.

18. The method according to claim 13, wherein electric current flowing in the coils at the top portion and the middle portion in the step (d) respectively ranges from 25 A to 30 A, and that at the bottom portion is 0 A.

19. The method according to claim 1, wherein the metal layer comprises a tungsten silicide layer.

20. The method according to claim 1, wherein the hard mask layer comprises a stacked structure of an anti reflective coating and a nitride film.
